(19) United States
(12) Patent Application Publication
(10) Pub. No.: US 2025/0204123 A1
(43) Pub. Date: Jun. 19, 2025

(54) LIGHT-EMITTING DEVICE

(71) Applicant: NICHIA CORPORATION, Anan-shi (JP)

(72) Inventors: Shumpei FUJIWARA, Anan-shi (JP); Shinya OKURA, Tokushima-shi (JP)

(73) Assignee: NICHIA CORPORATION, Anan-shi (JP)

(21) Appl. No.: 18/975,014

(22) Filed: Dec. 10, 2024

(30) Foreign Application Priority Data
Dec. 15, 2023 (JP) 2023-212490

(51) Int. Cl. H10H 29/14; H10H 29/80; H10H 29/85; H10H 29/851

(52) U.S. Cl. CPC H10H 29/142; H10H 29/8512; H10H 29/8514; H10H 29/857; H10H 29/942

(57) ABSTRACT

A light-emitting device includes a substrate; a frame disposed on an upper surface of the substrate; a first light-emitting element disposed on the upper surface of the substrate and within a first region along an inner periphery of the frame; a second light-emitting element disposed on the upper surface of the substrate and within a second region surrounded by the first region; a wall part disposed on the upper surface of the substrate, contacting the frame, and extending from the inner periphery of the frame toward the second region; a wavelength conversion member disposed on the upper surface of the substrate and within a region surrounded by the frame, and covering the wall part, the first light-emitting element, and the second light-emitting element; and a circuit including a first drive circuit that drives the first light-emitting element and a second drive circuit that drives the second light-emitting element.

### CROSS-REFERENCE TO RELATED APPLICATIONS

This application is based on and claims priority to Japanese Patent Application No. 2023-212490, filed on Dec. 15, 2023, the entire contents of which are incorporated herein by reference.

### TECHNICAL FIELD

The present disclosure relates to a light-emitting device.

### BACKGROUND

A light-emitting device including a first frame disposed on a substrate, a second frame disposed on the substrate and surrounding the first frame, at least one first light-emitting element disposed on the substrate and located inward of the first frame, and a plurality of second light-emitting elements disposed on the substrate and located between the first frame and the second frame is known (see Japanese Patent Publication No. 2020-53166, for example).

### SUMMARY

An object of one embodiment of the present disclosure is to reduce a difference in chromaticity when a plurality of light-emitting elements are driven by a plurality of circuits in a light-emitting device.

A light-emitting device according to one embodiment of the present disclosure includes a substrate having an upper surface; a frame disposed on the upper surface of the substrate; a first light-emitting element disposed on the upper surface of the substrate and within a first region along an inner periphery of the frame; a second light-emitting element disposed on the upper surface of the substrate and within a second region surrounded by the first region; a wall part disposed on the upper surface of the substrate, contacting the frame, and extending from the inner periphery of the frame toward the second region in a plan view; a wavelength conversion member disposed on the upper surface of the substrate and within a region surrounded by the frame, and covering the wall part, the first light-emitting element, and the second light-emitting element; and a circuit including a first drive circuit configured to drive the first light-emitting element and a second drive circuit configured to drive the second light-emitting element.

### BRIEF DESCRIPTION OF THE DRAWINGS

FIG. 1 is a perspective view illustrating a light-emitting device according to a first embodiment;

FIG. 2 is a perspective view of the light-emitting device illustrated in FIG. 1, from which a wavelength conversion member is removed;

FIG. 3 is a partial plan view illustrating a frame and the inside of the frame of the light-emitting device illustrated in FIG. 2;

FIG. 4 is a cross-sectional view taken through line IV-IV of FIG. 3;

FIG. 5 is a cross-sectional view taken through line V-V of FIG. 3; and

FIG. 6 is a circuit diagram of the light-emitting device according to the first embodiment.

### DETAILED DESCRIPTION

In the following, embodiments of the present disclosure will be described with reference to the drawings. In the following description, terms indicating specific directions and positions (for example, “upper,” “upward,” “lower,” “downward,” and other terms including these terms) are used as necessary. These terms are used to facilitate understanding of the present invention with reference to the drawings, and the technical scope of the present invention is not limited by the meaning of these terms. The same reference numerals appearing in a plurality of drawings refer to the same or similar portions or members.

Further, the following embodiments exemplify a light-emitting device and the like to embody the technical ideas of the present invention, and the present invention is not limited to the following description. In addition, unless otherwise specified, the dimensions, materials, shapes, relative arrangements, and the like of components described below are not intended to limit the scope of the present invention thereto, but rather are described as examples. The contents described in one embodiment can be applied to other embodiments and modifications. The sizes, positional relationships, and the like of members illustrated in the drawings may be exaggerated for clearer illustration. Furthermore, to avoid excessive complication of the drawings, a schematic view in which some elements are not illustrated may be used, or an end view illustrating only a cut surface may be used as a cross-sectional view. The term “rectangular shape” in the present specification allows a variation in an angle of each of the four corners within a range of 90 degrees±5 degrees, and includes an approximate rectangular shape such as a rectangular shape with chamfered or rounded corners. The term “rectangular shape” in the present specification encompasses a rectangle shape and a square shape.

### First Embodiment

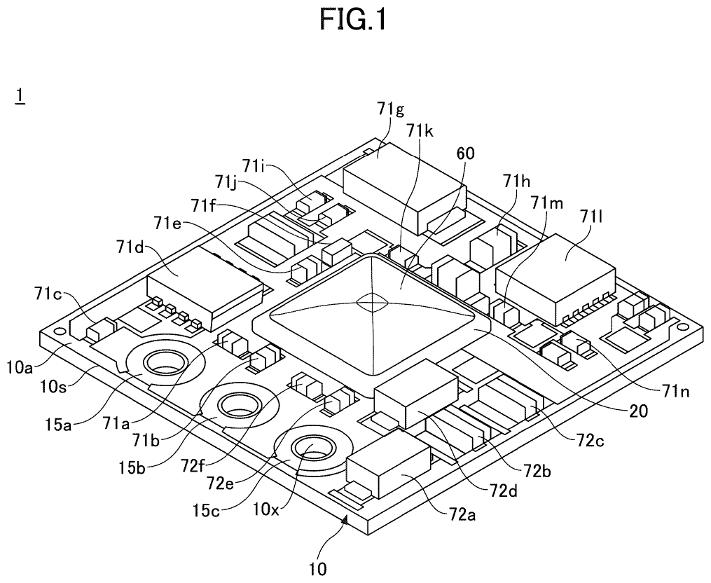

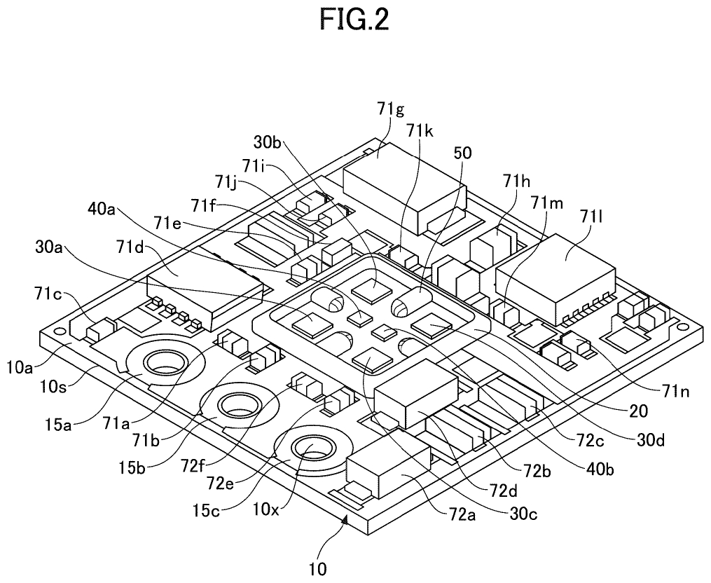

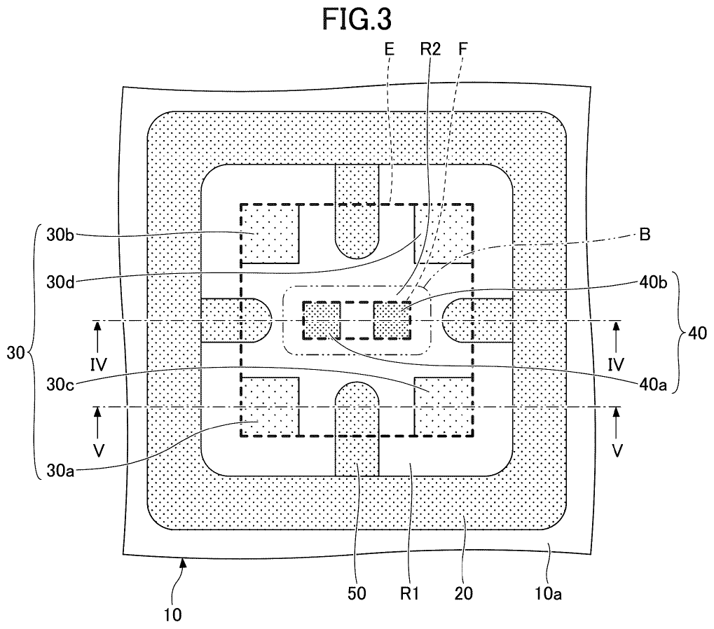

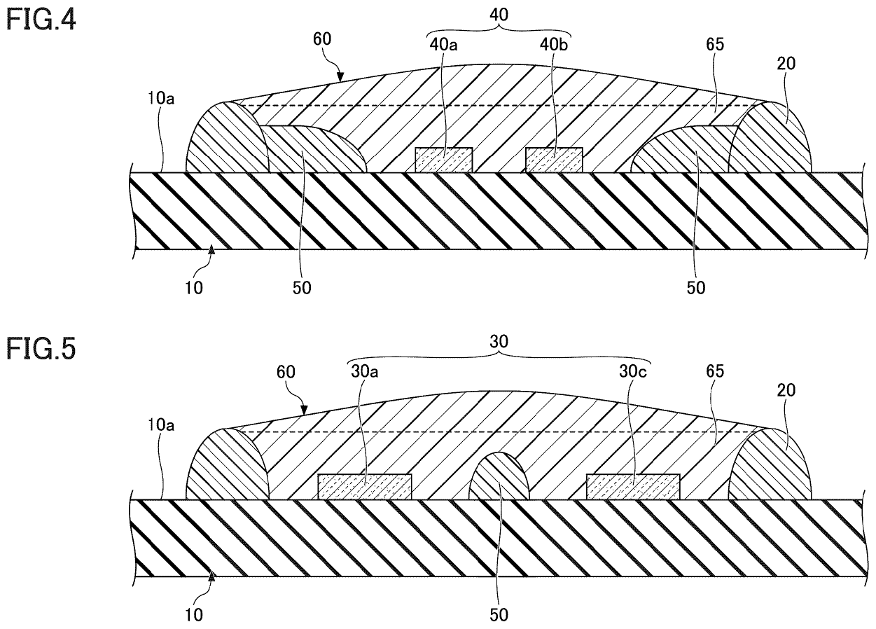

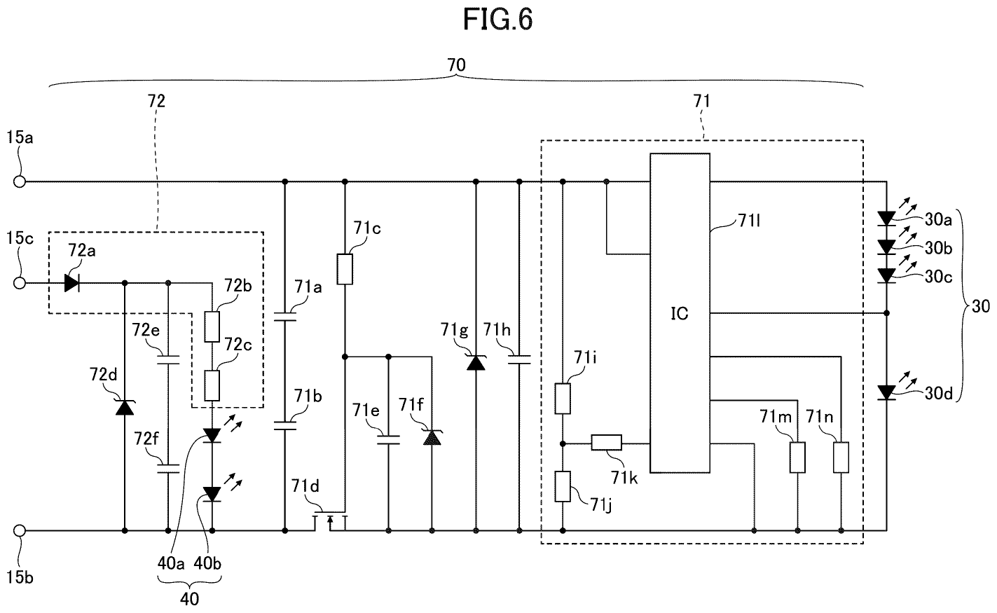

FIG. 1 is a perspective view illustrating a light-emitting device according to a first embodiment. FIG. 2 is a perspective view of the light-emitting device illustrated in FIG. 1, from which a wavelength conversion member is removed. FIG. 3 is a partial plan view illustrating a frame and the inside of the frame of the light-emitting device illustrated in FIG. 2. FIG. 4 is a cross-sectional view taken through line IV-IV of FIG. 3. FIG. 5 is a cross-sectional view taken through line V-V of FIG. 3. FIG. 6 is a circuit diagram of the light-emitting device according to the first embodiment. In FIG. 4 and FIG. 5, the wavelength conversion member not illustrated in FIG. 3 is illustrated.

The light-emitting device according to the first embodiment includes a substrate, the frame, one or more first light-emitting elements, one or more second light-emitting elements, a wall part, the wavelength conversion member, and a circuit. The light-emitting device according to the first embodiment can be used for in-vehicle lighting devices such as a stop lamp, a tail lamp, and the like of an automobile, a motorbike, or the like.

A light-emitting device 1 illustrated in FIG. 1 to FIG. 6 includes a substrate 10, a frame 20, first light-emitting elements 30a to 30d, second light-emitting elements 40a and 40b, a wall part 50, a wavelength conversion member 60, and a circuit 70. When the first light-emitting elements 30a to 30d are not distinguished, the first light-emitting elements 30a to 30d may be collectively referred to as first light-emitting elements 30. When the second light-emitting elements 40a and 40b are not distinguished, the second light-emitting elements 40a and 40b may be collectively referred to as second light-emitting elements 40.

As illustrated in FIG. 1 and FIG. 2, the substrate 10 has, for example, a rectangular shape in a plan view. The frame 20, the first light-emitting elements 30, the second light-emitting elements 40, the wall part 50, the wavelength conversion member 60, and the circuit 70 are disposed on an upper surface 10a of the substrate 10. The circuit 70 includes, for example, a plurality of electronic components each having a rectangular shape in a plan view.

In the example of FIG. 1 to FIG. 5, the frame 20 has a rectangular shape in a plan view. With this configuration, the plurality of electronic components each having a rectangular shape in a plan view can be efficiently arranged on the upper surface 10a of the substrate 10 along the outer periphery of the frame 20. The frame 20 may have a circular shape or an elliptical shape in a plan view.

As illustrated in FIG. 3, the upper surface 10a of the substrate 10 has a first region R1 and a second region R2 within the frame 20 in a plan view as regions where the light-emitting elements are arranged. The first region R1 is a frame-shaped region along the inner periphery of the frame 20 in a plan view. The second region R2 is a region surrounded by the first region R1 and including the center of the frame 20 in a plan view. In FIG. 3, B indicates a boundary between the first region R1 and the second region R2. In FIG. 3, a two-dot dash line indicating the boundary B is an imaginary line for convenience of description.

The first light-emitting elements 30 are arranged within the first region R1 on the upper surface 10a of the substrate 10. The first light-emitting elements 30a to 30d can have substantially the same size and a rectangular shape in a plan view, for example. For example, each of the first light-emitting elements 30a to 30d has a square shape in a plan view with one side being approximately 1 mm. In the light-emitting device 1, the first light-emitting elements 30a to 30d are connected to each other in series, for example.

In a case where the light-emitting device 1 includes a plurality of first light-emitting elements 30 each having a rectangular shape in a plan view, and the shape of the frame 20 in a plan view is a rectangle, the plurality of first light-emitting elements 30 are preferably arranged at the corner portions of the rectangle. The length of each of the sides constituting the rectangle-shaped frame 20 can be approximately 3 mm or more and 8 mm or less according to the size of a desired light-emitting surface. In a case where the light-emitting device 1 includes the four first light-emitting elements 30a to 30d, the first light-emitting elements 30a to 30d are preferably arranged at the corner portions of the rectangle of the frame 20 as illustrated in FIG. 3. This makes it easy to arrange the four first light-emitting elements 30a to 30d in a small space within the rectangle-shaped frame 20. Arranging the first light-emitting elements 30 at the corner portions of the rectangle means that the four rectangular first light-emitting elements 30a to 30d are arranged one by one in four rectangular regions obtained by dividing the rectangle into two rows and two columns in a plan view. In this case, it is preferable that two sides constituting a part of the inner periphery of the rectangle-shaped frame 20 and two sides of a corresponding first light-emitting element 30 facing the inner periphery of the rectangle-shaped frame 20 are substantially parallel to each other in a plan view.

In a case where the light-emitting device 1 includes a plurality of first light-emitting elements 30, and the shape of the frame 20 in a plan view is a rectangle, the plurality of first light-emitting elements 30 are preferably arranged so as to collectively form a rectangle in the first region R1 in a plan view. This makes it easy to arrange the plurality of first light-emitting elements 30 (the first light-emitting elements 30a to 30d) in a small space within the rectangle-shaped frame 20.

For example, the first light-emitting elements 30 can be arranged in a matrix so as to collectively form a rectangle, which is similar to a rectangular region surrounded by the frame 20. In the example of FIG. 3, the first light-emitting elements 30a to 30d having a rectangular shape in a plan view are arranged in two rows and two columns so as to collectively form a rectangle E in a plan view.

The second light-emitting elements 40 are arranged within the second region R2 on the upper surface 10a of the substrate 10. Specifically, the second light-emitting elements 40 are arranged on the upper surface 10a of the substrate 10 and located inward of the first light-emitting elements 30. The second light-emitting elements 40a and 40b can have substantially the same size and a rectangular shape in a plan view. The area of one second light-emitting element 40 is preferably smaller than the area of one first light-emitting element 30 in a plan view. With this configuration, the second light-emitting elements 40 can be arranged in a small space located inward of the first light-emitting elements 30. For example, each of the second light-emitting elements 40a and 40b in a plan view has a square shape with one side being approximately 0.6 mm. The second light-emitting elements 40a and 40b are connected to each other in series, for example.

One or more second light-emitting elements 40 are preferably arranged in the second region R2 so as to collectively form a rectangle in a plan view. This makes it easy to arrange the second light-emitting elements 40 in a small space located inward of the first light-emitting elements 30. In the example of FIG. 3, the second light-emitting elements 40a and 40b are arranged so as to collectively form a rectangle in a plan view. Specifically, the second light-emitting elements 40a and 40b are arranged such that three sides of the outer periphery of each of the second light-emitting elements 40a and 40b overlap a rectangle F indicated by a dashed line. It is preferable that the center of the rectangle E coincides with the center of the rectangle F in a plan view. Accordingly, the center of emission of the first light-emitting elements 30a to 30d can coincide with the center of emission of the second light-emitting elements 40a and 40b, and thus an optical system such as a lens can be easily designed. In FIG. 3, the dashed lines indicating the rectangle E and the rectangle F are imaginary lines for convenience of description.

The wall part 50 is disposed on the upper surface 10a of the substrate 10, contacts the frame 20, and extends from the inner periphery of the frame 20 toward the second region R2 in a plan view. The light-emitting device 1 may include one or more wall parts 50. In a case where the light-emitting device 1 includes a plurality of wall parts 50, and the shape of the frame 20 in a plan view is a rectangle, the plurality of wall parts 50 are preferably disposed to extend from two opposite sides of the rectangle toward the second region R2 in a plan view.

In the example of FIG. 3, the wall part 50 includes four wall parts 50, and each of the four wall parts 50 is disposed between two adjacent first light-emitting elements 30 in a plan view. Specifically, one wall part 50 is disposed between the first light-emitting element 30a and the first light-emitting element 30b, one wall part 50 is disposed between the first light-emitting element 30a and the first light-emitting element 30c, one wall part 50 is disposed between the first light-emitting element 30b and the first light-emitting element 30d, and one wall part 50 is disposed between the first light-emitting element 30c and the first light-emitting element 30d. That is, the wall part 50 includes four wall parts disposed to extend from the four respective sides of the rectangle of the frame 20 toward the second region R2. The wall part 50 may be disposed to extend along the entirety of opposing lateral surfaces of adjacent first light-emitting elements 30, or may be disposed to extend partway along the opposing lateral surfaces of two adjacent first light-emitting elements 30.

The wavelength conversion member 60 is disposed on the upper surface 10a of the substrate 10 and within a region (i.e., the first region R1 and the second region R2) surrounded by the frame 20, and covers the wall part 50, the first light-emitting elements 30, and the second light-emitting elements 40. Further, the wavelength conversion member 60 covers the inner periphery of the frame 20 and covers at least a portion of the frame 20 in the height direction, which is continuous with the inner periphery of the frame 20. The outer periphery of the frame 20 is not covered by the wavelength conversion member 60. The upper surface of the wavelength conversion member 60 constitutes a light-emitting surface of the light-emitting device 1. The wavelength conversion member 60 has, for example, a substantially rectangular shape in a plan view. The upper surface of the wavelength conversion member 60 is positioned higher than the upper surface of the frame 20. The wavelength conversion member 60 has light transmissivity so as to transmit light emitted from the first light-emitting elements 30 and the second light-emitting elements 40. The wavelength conversion member 60 can contain a wavelength conversion material such as phosphor particles. For example, in the light-emitting device 1, the first light-emitting elements 30 and the second light-emitting elements 40 are light-emitting elements that emit blue light, and the wavelength conversion member 60 contains phosphor particles that are excited by the blue light to emit red light. Accordingly, the light-emitting device 1 can serve as a light-emitting device that emits red light. The light-emitting device 1 can be used for lighting devices such as a stop lamp, a tail lamp, and the like of an automobile, a motorbike, or the like.

The circuit 70 includes wiring and electronic components disposed on the substrate 10. As illustrated in FIG. 6, the circuit 70 includes a first drive circuit 71 configured to drive the first light-emitting elements 30 and a second drive circuit 72 configured to drive the second light-emitting elements 40. The circuit 70 includes electronic components 71i to 71n constituting the first drive circuit 71 and electronic components 72a to 72c constituting the second drive circuit 72. The circuit 70 may include electronic components other than the electronic components 71i to 71n and the electronic components 72a to 72c. In the circuit 70, the first drive circuit 71 and the second drive circuit 72 can be driven independently from each other. That is, the circuit 70 can cause the first light-emitting element 30 and the second light-emitting element 40 to emit light simultaneously or emit light at different timings. The first light-emitting elements 30 can be used for, for example, an automotive stop lamp, and the second light-emitting element 40 can be used for, for example, an automotive tail lamp.

The light-emitting device 1 preferably includes three or more connection terminals arranged along the outer periphery of the upper surface 10a of the substrate 10 in a plan view, and configured to be connected to the circuit 70. The light-emitting device 1 including the three or more connection terminals allows the first light-emitting elements 30 and the second light-emitting elements 40 to be driven independently from each other. Further, by arranging a plurality of connection terminals along the outer periphery of the upper surface 10a, a heat sink is less likely to interfere with the plurality of connection terminals when the heat sink is disposed directly under a light source or an electronic component mounted on the substrate 10.

In the example of FIG. 1, three connection terminals 15a, 15b, and 15c are arrange along a first side 10s of the outer periphery of the first surface 10a in a plan view, and are connected to the wiring. The shape of the upper surface 10a is substantially a rectangle, and the first side 10s is one of the sides of the rectangle. For example, the connection terminals 15a, 15b, and 15c are provided around respective through holes 10x extending through the substrate 10.

The connection terminals 15a and 15c are, for example, power input terminals, and the connection terminal 15b is, for example, a GND terminal. The connection terminals 15a, 15b, and 15c can be composed of an electrically conductive material such as a metal such as gold, silver, copper, or aluminum. When the light-emitting device 1 is mounted in a socket or the like, external plugs (for example, feeding terminals) can be inserted into the respective through holes 10x and electrically connected to the respective connection terminals 15a, 15b, and 15c. Four or more connection terminals may be arranged along the outer periphery of the first surface 10a in a plan view.

As described above, the light-emitting device 1 includes the wall part 50 that contacts the frame 20 and extends from the inner periphery of the frame 20 toward the second region R2 in a plan view. Accordingly, a difference in chromaticity can be made less likely to occur between light emitted from the light-emitting device 1 when only the first light-emitting elements 30 emit light and light emitted from the light-emitting device 1 when only the second light-emitting elements 40 emit light. This will be described in detail below.

In the light-emitting device 1, the first light-emitting elements 30 are arranged in the first region along the inner periphery of the frame 20, and the second light-emitting elements 40 are located closer to the center of the frame 20 than the first light-emitting elements 30 are. The wavelength conversion member 60 covers the first light-emitting elements 30 and the second light-emitting elements 40. Therefore, if the light-emitting device 1 does not include the wall part 50 and causes only the second light-emitting elements 40 to emit light, of the light emitted from the second light-emitting elements 40, light traveling in the lateral direction (that is, traveling from the second light-emitting elements 40 toward the frame 20) propagates through the wavelength conversion member 60 and travels a long distance to reach the frame 20.

An example in which the second light-emitting elements 40 emit blue light and the wavelength conversion material contained in the wavelength conversion member 60 is a red phosphor will be described. For example, the absorption spectrum of the red phosphor has a peak in the vicinity of 450 nm, which is the wavelength range of blue light. The red phosphor absorbs blue light emitted from the second light-emitting elements 40, and is excited by the blue light to emit red light. Accordingly, the light-emitting device 1 can emit red light. In the absorption spectrum and the emission spectrum of the phosphor, there is a region where a longer wavelength region of the absorption spectrum and a shorter wavelength region of the emission spectrum overlap each other. Therefore, if light that is wavelength-converted by the red phosphor propagates a long distance through the wavelength conversion member 60, red light on the short wavelength side of the wavelength-converted red light is further wavelength-converted by the red phosphor. That is, in the case of only the second light-emitting elements 40 emitting light, the longer the distance that light emitted from the second light-emitting elements 40 travels to reach the frame 20, the more components on the short wavelength side of red light are absorbed. Thus, of red light emitted from the upper surface of the wavelength conversion member 60, the emission amount of red light on the short wavelength side of the emission spectrum of the red phosphor is reduced, and red light on the long wavelength side tends to be emitted.

In contrast, the first light-emitting elements 30 are located near the frame 20, and thus the distance that light emitted from the first light-emitting elements 30 travels to reach the frame 20 is shorter than the distance that light emitted from the second light-emitting elements 40 travels to reach the frame 20. Therefore, when the light is emitted from the first light-emitting elements 30, components on the short wavelength side of red light are absorbed to a smaller extent than when the light is emitted from the second light-emitting element 40. As a result, the emission spectrum of the red light emitted from the light-emitting device 1 is closer to the emission spectrum of the red phosphor when only the second light-emitting elements 40 emit light than when only the first light-emitting elements 30 emit light. That is, a difference in chromaticity would occur between light emitted from the light-emitting device 1 when only the first light-emitting elements 30 emit light and light emitted from the light-emitting device 1 when only the second light-emitting elements 40 emit light.

In view of the above, according to the present embodiment, the light-emitting device 1 includes the wall part 50 that contacts the frame 20 and extends from the inner periphery of the frame 20 toward the second region R2 in a plan view. Therefore, of light emitted from the second light-emitting elements 40, light traveling toward the frame 20 reaches the wall part 50 before reaching the frame 20. Thus, of the light emitted from the second light-emitting elements 40, the light traveling toward the frame 20 propagates a short distance through the wavelength conversion member 60, and thus components on the short wavelength side of red light can be absorbed to a smaller extent. As a result, a difference in chromaticity can be made less likely to occur between light emitted from the light-emitting device 1 when only the first light-emitting elements 30 emit light and light emitted from the light-emitting device 1 when only the second light-emitting elements 40 emit light. The difference in chromaticity between when only the first light-emitting elements 30 emit light and when only the second light-emitting elements 40 emit light can be adjusted by, for example, the number, the widths, the lengths, and the like of wall parts 50.

Further, of the light emitted from the first light-emitting elements 30 and the second light-emitting elements 40, light traveling in a lateral direction or an oblique direction is reflected by the wall part 50 and travels upward, and thus the light extraction efficiency of the light-emitting device 1 can be improved.

The light-emitting device 1 according to the present embodiment includes the first light-emitting elements 30, the second light-emitting elements 40, and the wavelength conversion member 60. In addition, light emitted from the light-emitting device 1 includes light obtained by using the wavelength conversion member 60 to wavelength-convert light emitted from the first light-emitting elements 30 and from the second light-emitting elements 40. Accordingly, for example, the light-emitting device 1 can emit red light by including light-emitting elements that emit blue light as the first light-emitting elements 30 and the second light-emitting elements 40, and allowing phosphor particles that are excited by the blue light to emit red light to be contained in the wavelength conversion member 60, for example. Typically, as light-emitting devices that emit red light, light-emitting devices using light-emitting elements that emit red light are used in many fields. In the present embodiment, blue light-emitting diodes are used as the first light-emitting elements 30 and the second light-emitting elements 40. Therefore, as compared to when red light-emitting diodes are used as the first light-emitting elements 30 and the second light-emitting elements 40, good temperature characteristics can be obtained. That is, when the light-emitting device 1 is used for a lighting device for a vehicle or the like, the environmental temperature in which the first light-emitting elements 30 and the second light-emitting elements 40 are used may be a high temperature exceeding 100° C. In general, the luminous flux maintenance factor of a blue light-emitting diode at a high temperature is higher than the luminous flux maintenance factor of a red light-emitting diode, and thus the blue light-emitting diode can maintain high luminance during a high-temperature operation as compared to when the red light-emitting diode is used.

In the present embodiment, the first light-emitting elements 30 and the second light-emitting elements 40 are not limited to light-emitting elements that emit blue light, and light-emitting elements that emit desired light such as ultraviolet light or green light can be used. Further, the wavelength conversion member 60 does not necessarily contain the phosphor that is excited by blue light to emit red light. A phosphor that can be excited by light emitted from the first light-emitting elements 30 and the second light-emitting elements 40 and emit light can be used. The light-emitting device 1 can emit light of a desired color by combining light emitted from the first light-emitting elements 30 and from the second light-emitting elements 40 with a phosphor contained in the wavelength conversion member 60.

Each component of the light-emitting device 1 according to the embodiment will be described in detail below.

### [Substrate 10]

The substrate 10 is a flat plate-shaped member having an insulating property. The substrate 10 has the upper surface 10a. The upper surface 10a has, for example, a square shape or a rectangular shape. The length of each side of the upper surface 10a can be, for example, approximately 1 cm or more and 3 cm or less. If the upper surface 10a has a square shape or a rectangular shape, each corner of the square shape or the rectangular shape may be chamfered or the like. The upper surface 10a may have a circular shape or a polygonal shape.

The substrate 10 is composed of, for example, a ceramic material such as aluminum oxide, aluminum nitride, or silicon nitride. The substrate 10 may be composed of an insulating resin material such as a phenol resin, an epoxy resin, a polyimide resin, a BT resin, or polyphthalamide. The substrate 10 may be a metal member having an insulating member disposed on the surface thereof.

Wiring and component-mounting lands connected to the wiring are disposed on the upper surface 10a of the substrate 10. Each of the wiring and the lands can be composed of an electrically conductive material such as a metal such as gold, silver, copper, or aluminum.

In the light-emitting device 1, a solder resist layer that covers the wiring and through which the lands and the connection terminals 15a, 15b, and 15c are exposed may be disposed on the upper surface 10a of the substrate 10. The solder resist layer can be composed of, for example, a photosensitive insulating resin or the like.

### [Frame 20]

The frame 20 is disposed on the upper surface 10a of the substrate 10. A region surrounded by the frame 20 is the light-emitting surface of the light-emitting device 1, and the light-emitting surface of the light-emitting device 1 is defined by the frame 20. Further, the frame 20 can be used as a dam for blocking an uncured wavelength conversion member 60 in a process of manufacturing the light-emitting device 1. The frame 20 surrounds the first light-emitting elements 30 and the second light-emitting elements 40 in a plan view. The width between the outer periphery and the inner periphery of the frame 20 in a plan view can be, for example, approximately 0.3 mm or more and 1 mm or less. The height of the frame 20 from the upper surface 10a of the substrate 10 can be, for example, approximately 0.3 mm or more and 1 mm or less.

The frame 20 may have, for example, a rectangular shape in a plan view. For example, if the frame 20 has a circular shape in a plan view, the distance between each of the four corners of the rectangle E illustrated in FIG. 3 and the inner periphery of the frame 20 is shorter than the distance between each of the four sides of the rectangle E and the inner periphery of the frame 20. As a result, the amount of light emitted from the vicinity of the four corners of the rectangle E in the light-emitting device 1 would be less than the amount of light emitted from the vicinity of the four sides of the rectangle E, and thus luminance unevenness would occur. When the frame 20 has a rectangular shape in a plan view, luminance unevenness is less likely to occur.

The frame 20 includes, for example, a resin. Examples of the resin include publicly-known light-transmissive resins such as silicone resins and epoxy resins. Among them, a light-transmissive resin such as a silicone resin having high reliability (specifically, a phenyl silicone resin, a dimethyl silicone resin, or the like) can be preferably used. The frame 20 preferably has a light shielding property. To have a light shielding property, the frame 20 can use a resin obtained by adding a pigment to any of the above-described light-transmissive resins. The frame 20 preferably has light reflectivity. To increase light reflectivity, a filler such as a white pigment may be added to the resin of the frame 20. As the filler, titanium oxide, aluminum oxide, zinc oxide, barium carbonate, barium sulfate, boron nitride, aluminum nitride, a glass filler, or the like can be suitably used. In addition, the frame 20 may further contain a black pigment such as carbon black, graphite, or titanium black.

### [First Light-Emitting Elements 30 and Second Light-Emitting Elements 40]

The first light-emitting elements 30 and the second light-emitting elements 40 are mounted on component-mounting lands on the substrate 10. The first light-emitting elements 30 and the second light-emitting elements 40 are preferably flip-chip mounted on the substrate 10. In flip-chip mounting, electrodes of the first light-emitting elements 30 and of the second light-emitting elements 40 can be electrically bonded to the lands on the substrate 10 by using bonding members such as eutectic solder, conductive paste, or bumps.

The first light-emitting elements 30 and the second light-emitting elements 40 are, for example, light-emitting diodes. The first light-emitting elements 30 and the second light-emitting elements 40 can be of any specific configuration as long as the first light-emitting elements 30 and the second light-emitting elements 40 can emit light having a predetermined wavelength. For example, each of the first light-emitting elements 30 and the second light-emitting elements 40 may be an LED chip housed in a package or may be an LED chip alone (a bare chip). The first light-emitting elements 30 and the second light-emitting elements 40 are preferably bare chips that are flip-chip mounted on the substrate 10. Accordingly, the size of the light-emitting device 1 can be reduced.

Each of the first light-emitting elements 30 and the second light-emitting elements 40 includes a semiconductor structure. The semiconductor structure includes an n-side semiconductor layer, a p-side semiconductor layer, and an active layer interposed between the n-side semiconductor layer and the p-side semiconductor layer. The active layer may be a single quantum well (SQW) structure or a multiple quantum well (MQW) structure including a plurality of well layers. The semiconductor structure includes a plurality of semiconductor layers formed of nitride semiconductors. The nitride semiconductors include semiconductors of all compositions obtained by varying the composition ratio x and y within their ranges in the chemical formula InₓAl_{y}Ga_{1-x-y}N (0≤x, 0≤y, x+y≤1). The peak emission wavelength of the active layer can be appropriately selected in accordance with the purpose. The active layer is configured to emit, for example, visible light or ultraviolet light.

The semiconductor structure may include a plurality of light-emitting parts each including an n-side semiconductor layer, an active layer, and a p-side semiconductor layer. If the semiconductor structure includes a plurality of light-emitting parts, well layers in the light-emitting parts may emit light having different peak emission wavelengths or the same peak emission wavelength. The same peak emission wavelength may include a variation of about several nanometers. A combination of peak emission wavelengths of light from the plurality of light-emitting parts can be appropriately selected. For example, if the semiconductor structure includes two light-emitting parts, combinations of light emitted from the light-emitting parts include blue light and blue light, green light and green light, ultraviolet light and ultraviolet light, blue light and green light, blue light and ultraviolet light, green light and ultraviolet light, and the like. For example, if the semiconductor structure includes three light-emitting parts, combinations of light emitted from the light-emitting parts include blue light, green light, and red light. Each of the light-emitting parts may include one or more well layers emitting light having different peak emission wavelengths from those of other well layers.

The wavelength of light emitted from the first light-emitting elements 30 and the second light-emitting elements 40 is appropriately set according to the application of the light-emitting device 1. The first light-emitting elements 30 and the second light-emitting elements 40 are, for example, blue light-emitting elements that emit blue light. If the first light-emitting elements 30 and the second light-emitting elements 40 are nitride-based semiconductor light-emitting elements that emit blue light, the forward current of the first light-emitting elements 30 and the second light-emitting elements 40 is, for example, 2.6 V or more.

### [Wall Part 50]

The height of the wall part 50 from the upper surface 10a of the substrate 10 is preferably less than the height of the frame 20. With this configuration, light that is wavelength-converted by the wavelength conversion member 60 can be reflected upward by the wall part 50 in a suitable manner, and thus the light extraction efficiency of the light-emitting device 1 can be improved. The height of the wall part 50 from the upper surface 10a of the substrate 10 can be less than the height of the frame 20 from the upper surface 10a of the substrate 10 by approximately 0.1 mm or more and 0.8 mm or less, for example.

The wall part 50 preferably has a top portion and inclined surfaces extending from the top portion toward the substrate 10, and each of the inclined surfaces preferably includes a curved surface projecting outward. For example, the wall part 50 preferably has a semi-circular or semi-elliptical shape in a cross-sectional view. Accordingly, a larger amount of light that is wavelength-converted by the wavelength conversion member 60 can be reflected upward by the wall part 50, and thus the light extraction efficiency of the light-emitting device 1 can be improved.

A center line of the wall part 50 in the longitudinal direction (that is, a direction in which the wall part 50 extends from the inner periphery of the frame 20 toward the second region R2) is, for example, parallel to or perpendicular to any side of the inner periphery of the rectangle of the frame 20 in a plan view. As used herein, the terms “parallel” and “perpendicular” allow a difference of ±5 degrees. The center line of the wall part 50 in the longitudinal direction is not necessarily parallel to or perpendicular to any side of the inner periphery of the rectangle of the frame 20 in a plan view. The width of the wall part 50 in a plan view can be, for example, approximately 0.3 mm or more and 1 mm or less.

The wall part 50 includes, for example, a resin. The wall part 50 can use any of the light-transmissive resins exemplified for the frame 20. The wall part 50 preferably has a light shielding property. To have a light shielding property, the wall part 50 can use a resin obtained by adding a pigment to any of the above-described light-transmissive resins. The wall part 50 preferably has light reflectivity. To increase light reflectivity, a filler such as a white pigment may be added to the resin of the wall part 50. As the filler of the wall part 50, any of the fillers exemplified for the frame 20 can be used.

### [Wavelength Conversion Member 60]

The wavelength conversion member 60 includes, for example, a resin. The wavelength conversion member 60 can use any of the light-transmissive resins exemplified for the frame 20. In a case where the wavelength conversion member 60 contains a phosphor, the phosphor is excited by light emitted from the first light-emitting elements 30 and the second light-emitting elements 40, and emits light having a wavelength different from the wavelength of the light emitted from the first light-emitting elements 30 and the second light-emitting elements 40. As an example, in a case where the first light-emitting elements 30 and the second light-emitting elements 40 are blue light-emitting elements, the wavelength conversion member 60 may contain a red phosphor. In this case, the first light-emitting elements 30 and the second light-emitting elements 40 can emit blue light, and the wavelength conversion member 60 can be excited by the blue light to emit red light. In this case, the light-emitting device 1 that can emit red light from the light-emitting surface can be achieved.

Examples of the phosphor include yttrium aluminum garnet based phosphors (for example, (Y, Gd)₃(Al, Ga)₅O₁₂:Ce), lutetium aluminum garnet based phosphors (for example, Lu₃(Al, Ga)₅O₁₂:Ce), terbium aluminum garnet based phosphors (for example, Tb₃(Al, Ga)₅O₁₂:Ce), CCA based phosphors (for example, Ca₁₀(PO₄)₆Cl₂:Eu), SAE based phosphors (for example, Sr₄Al₁₄O₂₅:Eu), chlorosilicate based phosphors (for example, Ca₈MgSi₄O₁₆Cl₂:Eu), silicate based phosphors (for example, (Ba, Sr, Ca, Mg)₂SiO₄:Eu), oxynitride based phosphors such as β-SiAlON based phosphors (for example, (Si, Al)₃(O, N)₄:Eu) and α-SiAlON based phosphors (for example, Ca(Si, Al)₁₂(O, N)₁₆:Eu), nitride based phosphors such as LSN based phosphors (for example, (La, Y)₃Si₆N₁₁:Ce), BSESN based phosphors (for example, (Ba, Sr)₂Si₅N₈:Eu), SLA based phosphors (for example, SrLiAl₃N₄:Eu), CASN based phosphors (for example, CaAlSiN₃:Eu), and SCASN based phosphors (for example, (Sr, Ca) AlSiN₃:Eu), fluoride based phosphors such as KSF based phosphors (for example, K₂SiF₆:Mn), KSAF based phosphors (for example, K₂(Si₁₋ₓAlₓ)F₆₋ₓ:Mn, where x satisfies 0<x<1), and MGF based phosphors (for example, 3.5MgO·0.5MgF₂·GeO₂:Mn), quantum dots having a Perovskite structure (for example, (Cs, FA, MA) (Pb, Sn) (F, Cl, Br, I)₃, where FA and MA represent formamidinium and methylammonium, respectively), II-VI quantum dots (for example, CdSe), III-V quantum dots (for example, InP), and quantum dots having a chalcopyrite structure (for example, (Ag, Cu) (In, Ga) (S, Se)₂).

As illustrated in FIG. 4 and FIG. 5, in a case where the wavelength conversion member 60 contains phosphor particles, the wavelength conversion member 60 may include a phosphor-containing portion 65, and the phosphor particles are present predominantly on the substrate 10 side of the phosphor-containing portion 65. In FIG. 4 and FIG. 5, a dashed line indicates a boundary between the phosphor-containing portion 65 and an upper portion of the wavelength conversion member 60. In FIG. 4 and FIG. 5, the dashed line indicating the boundary is an imaginary line for convenience of description. The boundary is not necessarily linear. The phosphor particles can be dispersed substantially uniformly in the phosphor-containing portion 65. In the wavelength conversion member 60, no phosphor particles need be present in the upper portion above the dashed line, or phosphor particles may be present in the upper portion in a smaller proportion than in the phosphor-containing portion 65.

It is known that the phosphor particles contained in the wavelength conversion member 60 convert a portion of absorbed light into heat. By causing the phosphor particles to be present predominantly on the substrate 10 side, heat generated by the phosphor particles can be efficiently released through the substrate 10. Further, by causing the phosphor particles to be present predominantly on the substrate 10 side, the phosphor particles can be present close to the first light-emitting elements 30 and the second light-emitting elements 40. This allows efficient wavelength conversion of light from the first light-emitting elements 30 and the second light-emitting elements 40.

To obtain the phosphor-containing portion 65, in a process of disposing the wavelength conversion member 60, an uncured resin containing phosphor particles can be disposed within the frame 20, and the phosphor particles can be sedimented on the upper surface 10a side of the substrate 10 within the frame 20. For example, when phosphor particles having a specific gravity greater than that of the uncured resin are selected, the phosphor particles can be sedimented before the uncured resin is cured. Alternatively, the phosphor particles may be forcibly sedimented by centrifugal sedimentation or the like.

The height of the wall part 50 is preferably less than the height of the phosphor-containing portion 65. Accordingly, a larger amount of light that is wavelength-converted by the wavelength conversion member 60 can be reflected upward by the wall part 50. Thus, the light extraction efficiency of the light-emitting device 1 can be improved. Further, by allowing the wall part 50 not to be disposed between the phosphor particles and the substrate 10, heat generated by the phosphor particles can be efficiently released through the substrate 10.

The upper surface of the wavelength conversion member 60 may project in a direction away from the upper surface 10a of the substrate 10. Accordingly, light emitted obliquely upward from the first light-emitting elements 30 and the second light-emitting elements 40 can be refracted in the substantially vertical direction at the interface between the projecting upper surface of the wavelength conversion member 60 and air. Thus, the light extraction efficiency of the light-emitting device 1 can be improved.

### [Circuit 70]

The electronic component 71l of the first drive circuit 71 is an integrated circuit configured to drive the first light-emitting elements 30. The first light-emitting elements 30a to 30d are connected in series to the output side of the electronic component 71l. A voltage is preferably supplied from the outside to the electronic component 71l without an active element (for example, a rectifier diode or the like) that causes a voltage drop. As a result, more of the voltage supplied from the outside can be used to drive the first light-emitting elements 30. In a case where the first light-emitting elements 30 are blue light-emitting diodes, the forward voltage is relatively high. Therefore, supplying the voltage from the outside to the electronic component 71l without an active element has a great significance. Inclusion of the integrated circuit as the electronic component 71l allows the first drive circuit 71 to control the value of a current flowing through the first light-emitting elements 30. The electronic component 71l, which is the integrated circuit, can be disposed on the substrate 10 and located outward of the frame 20. Thus, the amount of light absorbed by the electronic component 71l can be reduced. Further, in a case where the electronic component 71l has a rectangular shape in a plan view, the electronic component 71l can be easily disposed in a limited space of the upper surface 10a of the substrate 10 along the frame 20.

The electronic components 71i to 71k are resistors configured to set the operating voltage of the electronic component 71l. The electronic component 71m is a resistor configured to set the output current of the electronic component 71l. The electronic component 71n is a thermistor configured to detect the ambient temperature of the electronic component 71l. The electronic component 71l can control the value of the current flowing through the first light-emitting elements 30 based on the temperature detected by the electronic component 71n when the temperature of the substrate 10 rises.

The light-emitting device 1 may include the first light-emitting elements 30 connected in parallel to the electronic component 71l that is the integrated circuit. In the example of FIG. 6, the first light-emitting elements 30a to 30c connected to each other in series and the first light-emitting element 30d are connected in parallel to the electronic component 71l.

The first drive circuit 71 may have a first operation mode in which all the first light-emitting elements 30a to 30d emit light simultaneously, and a second operation mode in which only the first light-emitting elements 30a to 30c emit light. For example, the second operation mode is effective when a voltage applied between the connection terminal 15a and the connection terminal 15b drops and driving the four light-emitting elements simultaneously is difficult.

The first drive circuit 71 may be configured to include the integrated circuit, but does not necessarily include the integrated circuit. In a case where the first drive circuit 71 includes the integrated circuit, a large current can be supplied to the first light-emitting elements 30, and thus the emission intensity of the first light-emitting elements 30 can be increased. If it is not necessary to increase the emission intensity of the first light-emitting elements 30, the first drive circuit 71 may include a transistor instead of the integrated circuit, or may be configured to apply, to the first light-emitting elements 30, the voltage supplied from the outside via a resistor.

The circuit 70 may include a peripheral circuit of the first drive circuit 71 as necessary. In the example of FIG. 6, the circuit 70 includes electronic components 71a to 71h as the peripheral circuit of the first drive circuit 71.

The electronic components 71a and 71b are capacitors for noise suppression, and are connected in series between the connection terminal 15a and the connection terminal 15b. The electronic components 71a and 71b can reduce, for example, radio noise, noise induced in cables, and the like. The electronic components 71a and 72b are located closer to the input side than the electronic component 71g is. As used herein, the “input side” refers to a side closer to the connection terminals 15a and 15b in the circuit 70, and the “output side” refers to a side closer to the first light-emitting elements 30.

The electronic components 71c to 71f constitute a reverse connection protection circuit, and are connected to the output side of the electronic components 71a and 71b that are the capacitors. The electronic component 71c is a resistor, and controls the value of the current flowing through the electronic component 71d. The electronic component 71d is a metal-oxide-semiconductor field-effect transistor (MOSFET), and prevents the current from flowing from the connection terminal 15b to the connection terminal 15a. The electronic component 71e is a capacitor, and protects the electronic component 71d when a sudden overvoltage is applied in the reverse direction. The electronic component 71f is a Zener diode, and provides protection by preventing the voltage applied to the electronic component 71e side of the electronic component 71d from exceeding the maximum rating when the current is caused to flow from the connection terminal 15a to the connection terminal 15b.

One end of the electronic component 71c is electrically connected to the connection terminal 15a, and the other end of the electronic component 71c is electrically connected to a gate of the electronic component 71d, one end of the electronic component 71e, and a cathode of the electronic component 71f. Further, a source of the electronic component 71d is electrically connected to the connection terminal 15b, and an anode of the electronic component 71f is electrically connected to a drain of the electronic component 71d. In this circuit, the gate of the electronic component 71d is biased. Therefore, a voltage drop between the drain and the source of the electronic component 71d can be reduced, and thus the reverse connection protection circuit that reduces voltage consumption can be achieved.

The electronic component 71g is a transient voltage suppressor (TVS) diode that protects other electronic components when an overvoltage is applied, and is connected between the connection terminal 15a and the connection terminal 15b. The electronic component 71g is located closer to the output side than the electronic components 71c to 71f are, and is located closer to the input side than the first drive circuit 71 is.

The electronic component 71h is a capacitor for noise suppression, and is connected between the connection terminal 15a and the connection terminal 15b. The electronic component 71h is located closer to the output side than the electronic components 71c to 71f are, and is located closer to the input side than the first drive circuit 71 is.

The second drive circuit 72 is connected in series to the second light-emitting elements 40. The electronic component 72a is a rectifier diode, and an anode of the electronic component 72a is connected to the connection terminal 15c. The electronic component 72a can protect against reverse connection and can also protect the second light-emitting elements 40a and 40b from a negative surge. The electronic components 72b and 72c are resistors connected between a cathode of the electronic component 72a and the second light-emitting elements 40, and adjust a current flowing through the second light-emitting elements 40a and 40b.

As described, the second drive circuit 72 does not include an integrated circuit and a transistor, and includes the electronic component 72a, which is the rectifier diode, and the electronic components 72b and 72c, which are the resistors connected in series to the cathode of the rectifier diode. The second light-emitting elements 40 emit light due to the current supplied through the electronic component 72a, which is the rectifier diode, and the electronic components 72b and 72c, which are the resistors.

The circuit 70 may include a peripheral circuit of the second drive circuit 72 as necessary. In the example of FIG. 6, the circuit 70 includes electronic components 72d to 72f as the peripheral circuit of the second drive circuit 72. The electronic component 72d is a Zener diode for protecting the second light-emitting elements 40 from a positive surge, and are connected in series between the connection terminal 15c and the connection terminal 15b. The electronic components 72e and 72f are capacitors for noise suppression, and are connected in series between the connection terminal 15c and a connection terminal 15b. The electronic components 72e and 72f can reduce, for example, radio noise, noise induced in cables, and the like. The electronic components 72e and 72f are located closer to the output side than the electronic component 72d is.

The circuit configuration illustrated in FIG. 6 is one example, and the light-emitting device 1 may have any other circuit configuration. The circuit configuration of the light-emitting device 1 may be appropriately changed according to the application or the like of the light-emitting device 1.

According to one embodiment of the present disclosure, it is possible to reduce a difference in chromaticity when a plurality of light-emitting elements are driven by a plurality of circuits in a light-emitting device.

Although embodiments have been described in detail above, the above-described embodiments are non-limiting examples, and various modifications and substitutions can be made to the above-described embodiments without departing from the scope described in the claims.

What is claimed is:

1. A light-emitting device comprising:
a substrate having an upper surface;
a frame disposed on the upper surface of the substrate;
one or more first light-emitting elements disposed on the upper surface of the substrate and within a first region along an inner periphery of the frame;
one or more second light-emitting elements disposed on the upper surface of the substrate and within a second region surrounded by the first region;
one or more wall parts disposed on the upper surface of the substrate, contacting the frame, and extending from the inner periphery of the frame toward the second region in a plan view;
a wavelength conversion member disposed on the upper surface of the substrate and within a region surrounded by the frame, and covering the one or more wall parts, the one or more first light-emitting elements, and the one or more second light-emitting elements; and
a circuit comprising a first drive circuit and a second drive circuit, the first drive circuit being configured to drive the one or more first light-emitting elements and the second drive circuit being configured to drive the one or more second light-emitting elements.

2. The light-emitting device according to claim 1, wherein:
the one or more first light-emitting elements include a plurality of first light-emitting elements, and
the one or more wall parts are disposed between adjacent first light-emitting elements of the plurality of first light-emitting elements in the plan view.

3. The light-emitting device according to claim 2, wherein:
a shape of the frame in the plan view is a rectangle, and
the plurality of first light-emitting elements are arranged at corner portions of the rectangle.

4. The light-emitting device according to claim 3, wherein the one or more wall parts include a plurality of wall parts disposed to extend from two opposite sides of the rectangle toward the second region in the plan view.

5. The light-emitting device according to claim 3, wherein:
the plurality of first light-emitting elements include four first light-emitting elements arranged at respective corner portions of the rectangle, and
the one or more wall parts include four wall parts disposed to extend from four respective sides of the rectangle toward the second region.

6. The light-emitting device according to claim 1, wherein a height of each of the one or more wall parts is less than a height of the frame.

7. The light-emitting device according to claim 1, wherein an area of each of the one or more second light-emitting elements is smaller than an area of each of the one or more first light-emitting elements.

8. The light-emitting device according to claim 1, wherein the one or more first light-emitting elements include a plurality of first light-emitting elements arranged so as to collectively form a rectangle in the plan view.

9. The light-emitting device according to claim 1, wherein the one or more second light-emitting elements are arranged so as to collectively form a rectangle in the plan view.

10. The light-emitting device according to claim 1, further comprising:
three or more connection terminals arranged along an outer periphery of the upper surface of the substrate in the plan view, and configured to be connected to the circuit.

11. The light-emitting device according to claim 1, wherein:
the circuit includes an integrated circuit, and
the one or more first light-emitting elements are configured to be connected in parallel to the integrated circuit.

12. The light-emitting device according to claim 11, wherein the integrated circuit is disposed on the substrate and located outward of the frame.

13. The light-emitting device according to claim 1, wherein:
the wavelength conversion member contains phosphor particles and comprises a phosphor-containing portion, and
the phosphor particles are present predominantly on a substrate side of the phosphor-containing portion.

14. The light-emitting device according to claim 13, wherein a height of each of the one or more wall parts is less than a height of the phosphor-containing portion.

15. The light-emitting device according to claim 1, wherein:
the one or more first light-emitting elements and the one or more second light-emitting elements are configured to emit blue light, and
the wavelength conversion member is configured to be excited by the blue light to emit red light.
